(19) United States
(12) Patent Application Publication
(10) Pub. No.: US 2006/0231946 A1
(43) Pub. Date: Oct. 19, 2006

(54) Nanotube surface coatings for improved wettability

(75) Inventors: Lawrence S. Pan, Los Gatos, CA (US); Gang Gu, Palo Alto, CA (US); Jim Protsenko, San Jose, CA (US); Xuejiao Hu, Stanford, CA (US); Hongjie Dai, Cupertino, CA (US); Srinivas Rao, Saratoga, CA (US)

Correspondence Address: CARR & FERRELL LLP, 2200 GENG ROAD, PALO ALTO, CA, 94303, US

(73) Assignee: Molecular Nanosystems, Inc.

(21) Appl. No.: 11/107,599

(22) Filed: Apr. 14, 2005

(51) Int. Cl. H01L 23/34

(52) U.S. Cl. 257/712

(57) ABSTRACT

A thermal interface includes an array of generally aligned carbon nanotubes joined to a surface with a metal layer. The array of carbon nanotubes includes a coating on the ends of the carbon nanotubes for improved wetting of the metal layer to the ends of the carbon nanotubes so that the thermal resistance at the interface between the carbon nanotubes ends and the metal is reduced. A semiconductor device that employs a thermal interface of the invention, and a method for fabricating the thermal interfaces are also provided.

### STATEMENT REGARDING FEDERALLY SPONSORED RESEARCH OR DEVELOPMENT

This invention was made with United States Government support under Cooperative Agreement No. 70NANB2H3030 awarded by the Department of Commerce's National Institute of Standards and Technology. The United States has certain rights in the invention.

### BACKGROUND OF THE INVENTION

1. Field of the Invention

The present invention relates generally to the field of materials science and more particularly to forming structures that employ carbon nanotubes for thermal dissipation.

2. Description of the Prior Art

A carbon nanotube is a molecule composed of carbon atoms arranged in the shape of a cylinder. Carbon nanotubes are very narrow, on the order of nanometers in diameter, but can be produced with lengths on the order of microns. The unique structural, mechanical, and electrical properties of carbon nanotubes make them potentially useful in electrical, mechanical, and electromechanical devices. In particular, carbon nanotubes possess both high electrical and thermal conductivities in the direction of the longitudinal axis of the cylinder. For example, thermal conductivities of individual carbon nanotubes of 3000 W/m° K and higher at room temperature have been reported.

The high thermal conductivity of carbon nanotubes makes them very attractive materials for use in applications involving heat dissipation. For example, in the semiconductor industry, devices that consume large amounts of power typically produce large amounts of heat. The heat must be efficiently dissipated to prevent these devices from overheating and failing. Presently, such devices are coupled to large heat sinks, often through the use of a heat spreader.

In order to effectively use carbon nanotubes to transmit heat from a source to a sink, it is necessary to provide both a large number of aligned carbon nanotubes between the source and the sink, and good thermal conductivity from the carbon nanotubes to both the source and the sink. Dai et al. (e.g. U.S. Pat. No. 6,346,189), and others, have shown the ability to provide an array of carbon nanotubes grown essentially perpendicular to a surface. The array of carbon nanotubes grown according to the process of Dai et al. grows from a catalyst layer on the surface. While the carbon nanotubes are well attached to the catalyst layer from which they were grown, the opposite ends of the carbon nanotubes are unconstrained.

Therefore, what is needed is a way to attach the ends of an array of carbon nanotubes to a free surface such that the carbon nanotubes and the free surface adhere well to one another, and minimize the resistance to thermal conduction across the interface.

### SUMMARY

The present invention provides a thermal interface comprising a metal layer, an array of generally aligned carbon nanotubes, and a wetting layer disposed on the carbon nanotubes. The array of carbon nanotubes has an end disposed within the metal layer, and the wetting layer is disposed between the carbon nanotubes and the metal layer. For example, the ends of the carbon nanotubes can be coated with a palladium wetting layer for better adhesion to an indium metal layer. Optionally, the wetting layer can be coated with a passivation layer, for example of gold or platinum, to protect the wetting layer from oxidation.

The present invention also provides a semiconductor device comprising a heat generation source having a backside, a first cooling aid having a first surface, and a thermal interface of the invention between the backside of the heat generation sourceand the first surface of the first cooling aid. The heat generation source can be, for instance, a processor or microprocessor such as the Intel Pentium 4. In some embodiments the semiconductor device further comprises a catalyst layer on either the backside of the heat generation source or the surface of the first cooling aid. In these embodiments, the carbon nanotubes attach to the catalyst layer, and the metal layer of the thermal interface contacts a surface opposite to the catalyst layer. In additional embodiments, the semiconductor device further comprises a second cooling aid in thermal communication with the first cooling aid. Here, the first and second cooling aids can be, for instance, a heat spreader and a heat sink. Accordingly, some of these embodiments further comprise a second thermal interface between the first and second cooling aids.

The present invention further provides a method for fabricating a thermal interface. The method comprises forming an array of carbon nanotubes on a surface of a first object, coating the carbon nanotubes at a free end of the array with a wetting layer, and attaching a surface of a second object to the free end of the array. In some embodiments the surface of the first object includes a catalyst layer surface which can additionally be patterned. Additionally, attaching the surface of the second object to the free end of the array can include placing a foil of a metal between the free end of the array and the second surface, and heating the foil to near the melting point of the metal.

Coating the carbon nanotubes at the free end of the array with the wetting layer can include, for example, sputter coating or E-beam evaporation. The method can additionally comprise coating a passivation layer over the wetting layer. The passivation layer serves to protect the wetting layer from oxidizing during storage and handling prior to the step of attaching the surface of the second object to the free end of the array.

### BRIEF DESCRIPTION OF DRAWINGS

FIG. 1 is a schematic representation of a cross-section of a thermal interface, according to an embodiment of the invention, disposed between two surfaces.

FIG. 2A is a schematic representation of a cross-section of the thermal interface of FIG. 1 in greater detail.

FIG. 2B is a schematic representation of a cross-section of the thermal interface of FIG. 2A in still greater detail, according to a further embodiment of the invention.

FIG. 3 is a flow-chart depicting a method for fabricating a thermal interface according to an embodiment of the invention.

FIGS. 4-6 are schematic representations of cross-sections of a partially fabricated semiconductor device, including a thermal interface, at successive stages of fabrication according to an embodiment of the invention.

FIG. 7 is a Scanning Electron Microscope (SEM) micrograph of a thermal interface prepared according to an embodiment of the present invention.

FIG. 8 is a SEM micrograph showing a portion of the micrograph of FIG. 7 at higher resolution.

### DETAILED DESCRIPTION OF THE INVENTION

The present invention provides a thermal interface comprising an array of carbon nanotubes joined to a surface with a metal layer. The array of carbon nanotubes includes a coating on the carbon nanotubes for improved wetting of the metal to the carbon nanotubes so that the thermal resistance at the interface between the carbon nanotubes and the metal is reduced. The present invention also provides a semiconductor device that employs these thermal interfaces, and a method for fabricating the same.

FIG. 1 illustrates a thermal interface 100 of the present invention. The thermal interface 100 can be disposed, for example, between a heat generation source and a cooling aid. The heat generation source can be anything that produces heat and requires cooling like a semiconductor die or a laser diode. Likewise, the cooling aid can be anything that draws heat away from the heat generation source such as a thermal management aid, heat spreader, heat sink, or cold plate. In FIG. 1 the opposing surfaces that bracket the thermal interface 100 are first and second objects 110 and 120, respectively. Thus, for example, the first object 110 can be a semiconductor die while the second object 120 is a heat spreader. More generally, first and second objects 110 and 120 can be any two objects requiring a thermal interface that can provide good thermal conductivity therebetween.

The thermal interface 100 comprises an array of generally aligned carbon nanotubes 130 and a metal layer 140 that bonds one end of the array to the second object 120. The metal layer 140 is preferably a low melting point metal or eutectic alloy such an indium, tin, or a solder such as tin-silver, tin-lead, lead-silver, and tin-antimony. The array of carbon nanotubes 130 can be grown, for example, on a thin catalyst layer 150 as taught by Dai et al. in U.S. Pat. No. 6,232,706. It will be appreciated, however, that the present invention does not require that the array of carbon nanotubes 130 be prepared by the catalysis method of Dai et al., and any method that can produce a generally aligned array of carbon nanotubes extending from a surface is acceptable.

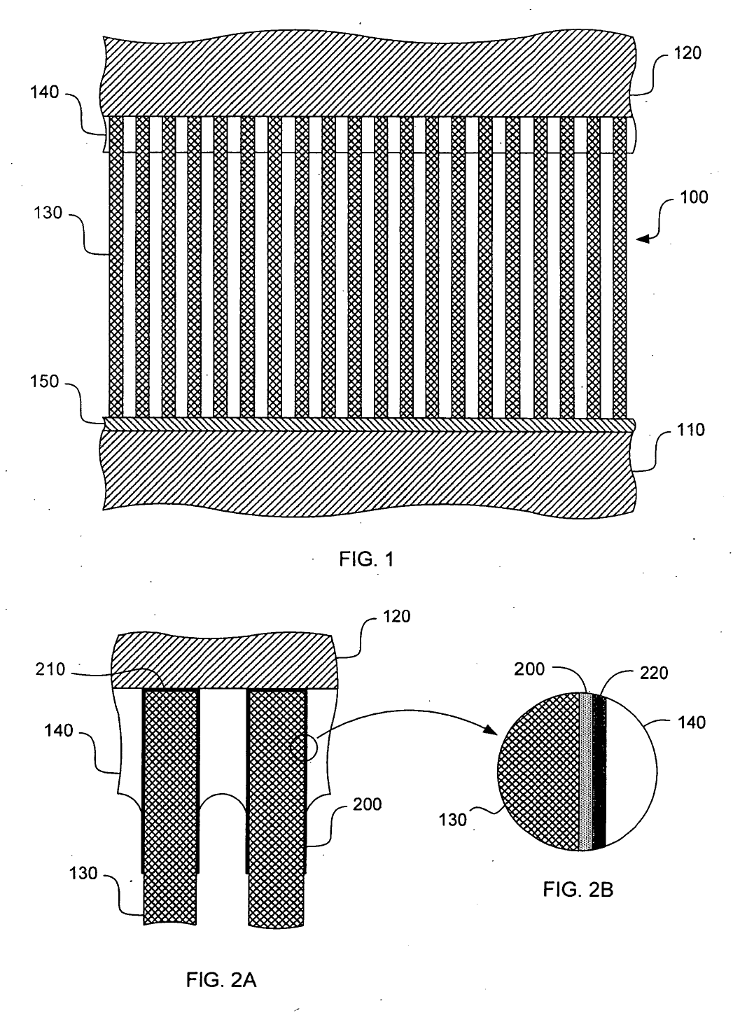

As shown in more detail in FIG. 2A, the thermal interface 100 of the invention also comprises a wetting layer 200 disposed on the carbon nanotubes 130. As shown, the wetting layer 200 helps the metal layer 140 wet the surfaces of the carbon nanotubes 130 for better adhesion and reduced thermal resistance between the metal layer 140 and the carbon nanotubes 130. For the purposes of clarity, several definitions will be adopted for describing carbon nanotubes 130. As used herein, “top” refers to that portion of the carbon nanotube 130 that can be seen if viewed along the longitudinal axis thereof, whether open or closed. As “top” is not meant to denote orientation, each carbon nanotube 130 includes two tops. “Side” refers to that portion of the carbon nanotube 130 that can be seen if viewed from a direction perpendicular to the longitudinal axis. “End” refers to that portion of the carbon nanotube 130 that lies between the top and a center thereof.

It will be appreciated that the wetting layer 200 on a side of a carbon nanotube 130 need not extend the entire length of the carbon nanotube 130, though in some embodiments it does. In some embodiments the wetting layer 200 covers about 10% of the length of the carbon nanotubes 130 as measured from the tops 210 of the carbon nanotubes 130 that are bonded to the second object 120. As shown in FIG. 2A, the wetting layer 200 can additionally extend over the tops 210 of the carbon nanotubes 130. It will be appreciated that although the tops 210 of the carbon nanotubes 130 are schematically represented as flat in FIG. 2A, in actuality the tops 210 are either open or closed by a generally hemispherical cap.

Suitable materials for the wetting layer 200 include palladium, chromium, titanium, vanadium, hafnium, niobium, tantalum, magnesium, tungsten, cobalt, zirconium, and various alloys of the listed metals. The composition of the wetting layer 200 should be chosen based on the composition of metal layer 140. For example, where the metal layer 140 includes indium, particularly suitable materials for the wetting layer 200 include palladium, chromium, and titanium. Preferably, the wetting layer 200 is continuous around the circumferences of the carbon nanotubes 130 and comprises at least a monolayer of the selected metal or alloy. It should be noted that the wetting layer 200 is not meant to replace the metal layer 140 and should not be formed to a thickness where the wetting layer 200 begins to fill the spaces between carbon nanotubes 130. The wetting layer 200 should be understood to be a coating on the ends of the carbon nanotubes 130.

As shown in FIG. 2B, in further embodiments an optional inert passivation layer 220 is disposed over the wetting layer 200. The passivation layer 220 can be desirable to prevent oxidation of the wetting layer 200, for example, during the period of time between the formation of the wetting layer 200 and such time as the array of carbon nanotubes 130 is bonded with the metal layer 140 to the second object 120. Metals that do not readily oxidize, such as gold and platinum, are suitable for the passivation layer 220. An exemplary thickness for the passivation layer 220 is about 20 nm.

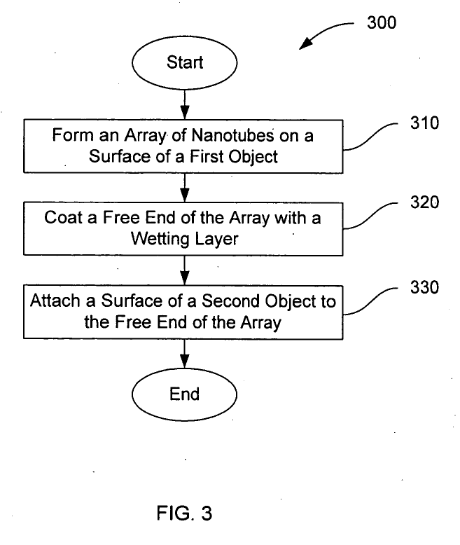

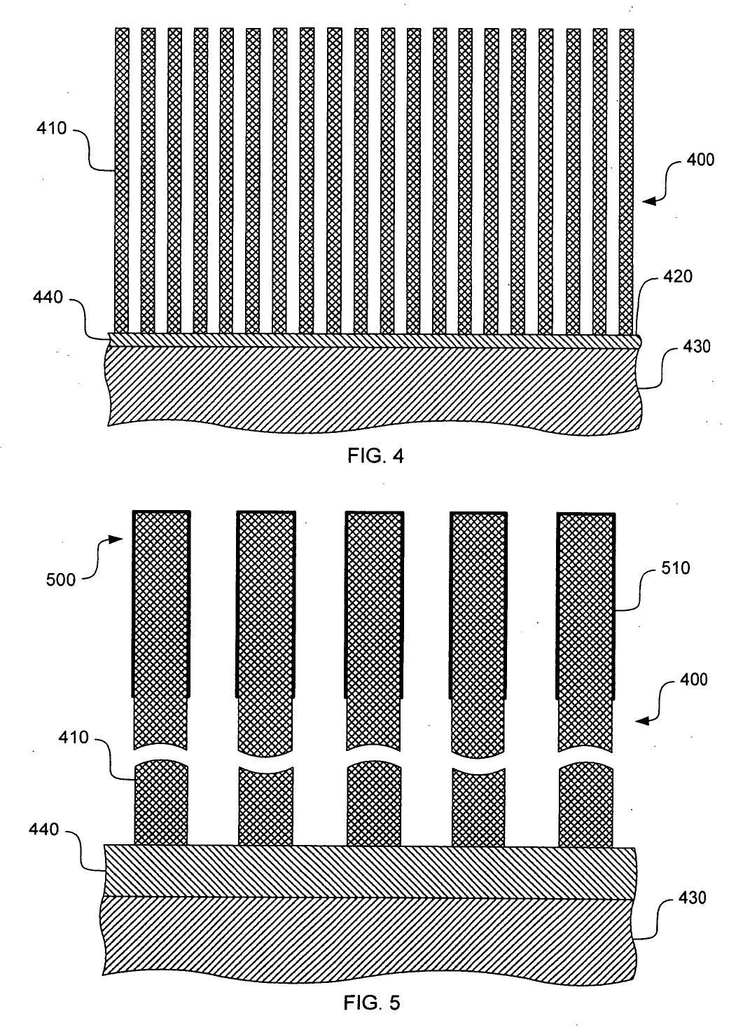

The present invention also provides a possible method 300 for fabricating a thermal interface, as illustrated by a flowchart in FIG. 3. The method 300 includes a step 310 of forming an array of carbon nanotubes on a surface of a first object, a step 320 of coating the carbon nanotubes at a free end of the array with a wetting layer, and a step 330 of attaching a surface of a second object to the free end of the array.

FIG. 4 illustrates the step 310 of forming an array 400 of carbon nanotubes 410 on a surface 420 of a first object 430. In the embodiment shown in FIG. 4, the surface 420 comprises a catalyst layer 440. In the illustrated embodiment, the step 310 includes providing the first object 430, forming the catalyst layer 440, and growing the array 400 of carbon nanotubes 410 on the catalyst layer 440. In other embodiments the carbon nanotubes 410 are grown directly on a surface of the first object 430 without the use of a catalyst. It will be appreciated that in those embodiments that employ the catalyst layer 440, the catalyst layer 440 can be patterned (not shown) to limit the growth of the carbon nanotubes 410 to selected regions on the first object 430. Growth of the carbon nanotubes 410 can be achieved, for example, by Chemical Vapor Deposition (CVD) as is well known in the art. The array 400 of carbon nanotubes 410 can have a height of between about 10μ and 100μ in some embodiments.

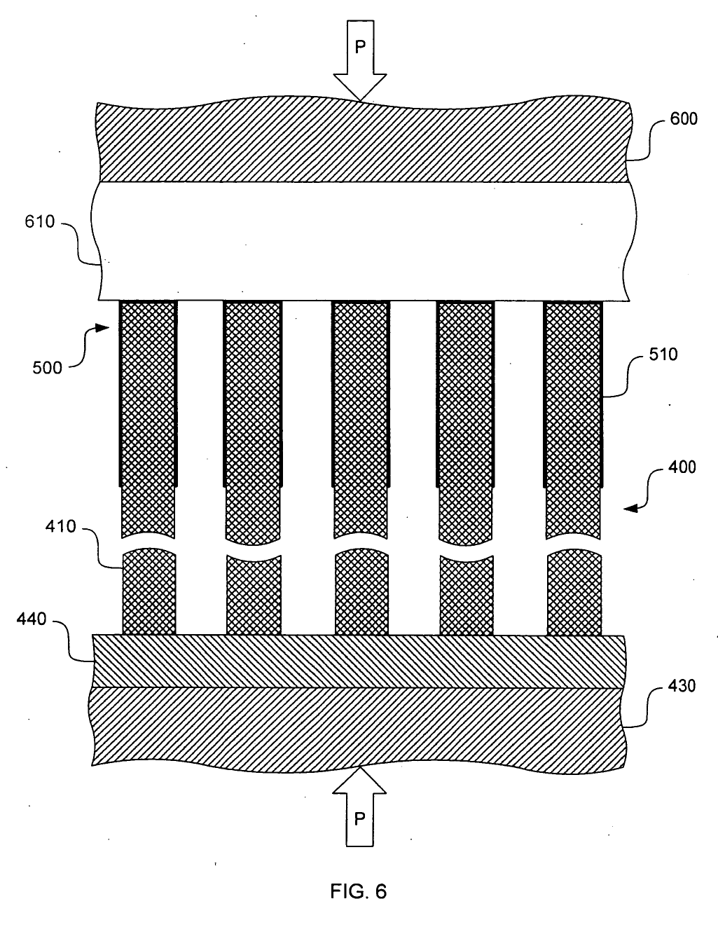

FIG. 5 illustrates the step 320 of coating the carbon nanotubes 410 at the free end 500 of the array 400 with a wetting layer 510. The wetting layer 510 can be formed on the sides and tops of the carbon nanotubes 410, for example, by well known processes such as E-beam evaporation and sputter coating. Both processes produce a vapor phase of the metal or alloy that condenses on the carbon nanotubes 410. To achieve good coating on the ends and the tops of the carbon nanotubes 410, where the wetting layer 510 is most needed, the array 400 should be oriented in the deposition chamber such that the free end is nearest to the vapor source. The invention is not limited to these two particular coating technologies, and many other techniques known in the art can alternately be used.

Some exemplary embodiments of step 320 are as follows. To produce a 20 nm thick wetting layer 510 of palladium, the step 320 includes placing the first object 430 having the array 400 of carbon nanotubes 410 disposed thereon in a sputter deposition chamber. Next, palladium is sputtered in a partial vacuum of about 5×10⁻³ Torr at a power of 50 W. In another embodiment, a 5 Å thick wetting layer 510 of titanium is obtained under the same conditions of vacuum and power. In still another embodiment, a 40 nm thick wetting layer 510 is obtained in a partial vacuum of about 5×10⁻³ Torr and at a power of 100 W.

In some embodiments a 50 Å thick wetting layer 510 of titanium is obtained by E-beam evaporation. In this embodiment the step 320 includes placing first object 430 having the array 400 of carbon nanotubes 410 disposed thereon in an evaporator chamber. The evaporator is operated at 2.5% of full power (full power for an exemplary evaporator is 10 kW) with a voltage of 10 kV under a vacuum of about 1×10⁻⁷ Torr. In another embodiment, a 500 Å thick wetting layer 510 of chromium is obtained under the same power and voltage conditions, but with a vacuum of about 1×10⁻⁶ Torr.

In some embodiments step 320 can further comprise coating the carbon nanotubes 410 at the free end 500 of the array 400 with a passivation layer 220 (FIG. 2B) over the wetting layer 510. The passivation layer 220 can be a relatively thin layer, in some embodiments on the order of 20 nm thick. An exemplary deposition process for sputtering gold includes sputtering for one minute in a partial vacuum of about 5×10⁻³ Torr at a power of 50 W and with an applied bias of 390V DC. An exemplary evaporation process for forming the passivation layer 220 includes evaporating gold at 10% of full power under a vacuum of about 1×10⁻⁶ Torr with a voltage of 10 kV for about 200 seconds.

FIG. 6 illustrates the step 330 of attaching the surface of a second object 600 to the free end 500 of the array 400. In an exemplary embodiment, a foil 610 of indium is placed between the free end 500 of the array 400 and the second object 600. Solders and other low melting point materials can also be employed. Next, pressure is applied between the first object 430 and the second object 600 while the entire assembly is heated to near the melting point of indium. Here, “near the melting point” should be understood to include temperatures below, at, and above the melting point. As the temperature is increased and the indium foil 610 softens, the ends of the carbon nanotubes 410 at the free end 500 push into the indium foil 610 until they are stopped by the surface of the second object 600 to produce the structure shown in FIG. 1. The effect of the wetting layer 510 is to allow the indium to wet the surfaces of the carbon nanotubes 410 for a better physical and thermal bond.

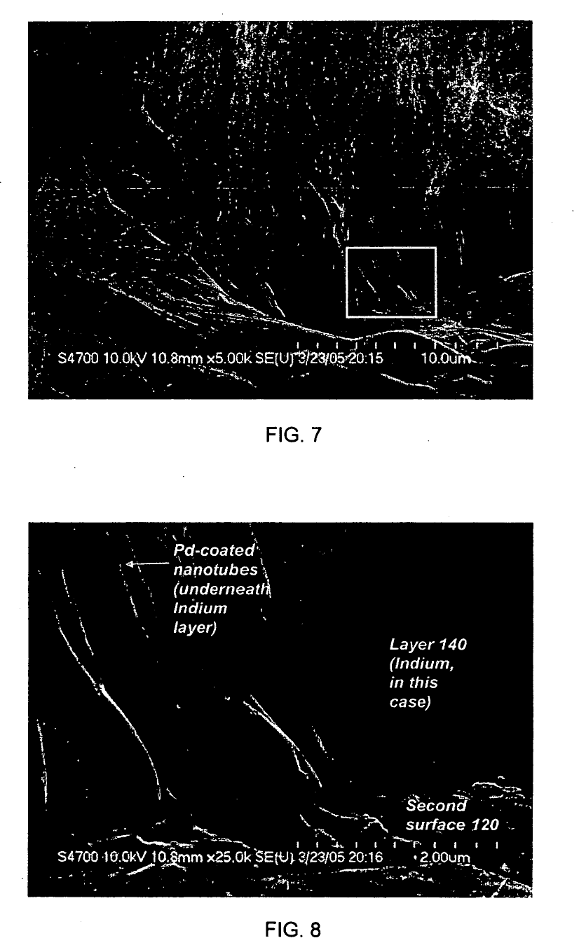

FIGS. 7 and 8 show Scanning Electron Microscope (SEM) micrographs of a thermal interface of the present invention. In FIG. 7 the scale bar represents a distance of 10μ. A box in the lower right corner of FIG. 7 shows an area that is imaged at higher resolution in FIG. 8. The scale bar in FIG. 8 represents a distance of 2μ. In FIGS. 7 and 8 palladium-coated carbon nanotubes are bonded to a surface with indium metal. To prepare the thermal interface, indium foil was pressed between the surface and an array of carbon nanotubes, having palladium-coated ends, at 200° C. in an argon atmosphere for 20 minutes.

In the foregoing specification, the invention is described with reference to specific embodiments thereof, but those skilled in the art will recognize that the invention is not limited thereto. Various features and aspects of the above-described invention may be used individually or jointly. Further, the invention can be utilized in any number of environments and applications beyond those described herein without departing from the broader spirit and scope of the specification. The specification and drawings are, accordingly, to be regarded as illustrative rather than restrictive. It will be recognized that the terms “comprising,” “including,” and “having,” as used herein, are specifically intended to be read as open-ended terms of art.

What is claimed is:

1. A thermal interface comprising:
a metal layer;
an array of generally aligned carbon nanotubes, the array having an end disposed within the metal layer; and
a wetting layer disposed on the carbon nanotubes at the end of the array, the wetting layer being disposed between the carbon nanotubes and the metal layer.

2. The thermal interface of claim 1 wherein the metal layer includes indium.

3. The thermal interface of claim 1 wherein a height of the array is between about 10μ and 100μ.

4. The thermal interface of claim 1 wherein the wetting layer includes palladium.

5. The thermal interface of claim 1 wherein the wetting layer includes chromium.

6. The thermal interface of claim 1 wherein the wetting layer includes titanium.

7. The thermal interface of claim 1 wherein the wetting layer comprises at least a monolayer coating.

8. The thermal interface of claim 1 further comprising a passivation layer disposed on the wetting layers of the carbon nanotubes, the passivation layer being disposed between the wetting layer and the metal layer.

9. The thermal interface of claim 8 wherein the passivation layer includes gold.

10. The thermal interface of claim 8 wherein the passivation layer includes platinum.

11. A semiconductor device comprising:
a heat generation source having a backside;
a first cooling aid having a first surface; and
a thermal interface between the backside of the heat generation source and the first surface of the first cooling aid, the thermal interface including
a metal layer,
an array of generally aligned carbon nanotubes, the array having a first end disposed within the metal layer, and
a wetting layer disposed on the carbon nanotubes at the end of the array, the wetting layer being disposed between the carbon nanotubes and the metal layer.

12. The semiconductor device of claim 11 further comprising a catalyst layer disposed on the backside of the heat generation source, wherein a second end of the array is attached to the catalyst layer.

13. The semiconductor device of claim 12 wherein the metal layer contacts the first surface of the first cooling aid.

14. The semiconductor device of claim 11 further comprising a catalyst layer disposed on the first surface of the first cooling aid, wherein a second end of the array is attached to the catalyst layer.

15. The semiconductor device of claim 14 wherein the metal layer contacts the backside of the heat generation source.

16. The semiconductor device of claim 11 further comprising a second cooling aid in thermal communication with the first cooling aid.

17. The semiconductor device of claim 16 further comprising a second thermal interface between the first cooling aid and the second cooling aid.

18. The semiconductor device of claim 11 wherein the heat generation source is a microprocessor.

19. The semiconductor device of claim 11 wherein the heat generation source is a semiconductor die.

20. The semiconductor device of claim 11 wherein the first cooling aid is a heat spreader.

21. The semiconductor device of claim 17 wherein first cooling aid is a heat spreader and the second cooling aid is a heat sink.

22. A method for fabricating a thermal interface, the method comprising:
forming an array of carbon nanotubes on a surface of a first object;
coating the carbon nanotubes at a free end of the array with a wetting layer; and
attaching a surface of a second object to the free end of the array.

23. The method of claim 22 wherein the surface of the first object includes a catalyst layer surface.

24. The method of claim 22 wherein coating the carbon nanotubes at the free end of the array with the wetting layer includes sputter coating.

25. The method of claim 22 wherein coating the carbon nanotubes at the free end of the array with the wetting layer includes E-beam evaporation.

26. The method of claim 22 wherein attaching the surface of the second object to the free end of the array includes placing a metal foil between the free end of the array and the second surface, and heating the foil to near its melting point.

27. The method of claim 22 wherein forming the array of carbon nanotubes on the surface of the first object includes patterning a catalyst layer.

28. The method of claim 22 further comprising coating the carbon nanotubes at the free end of the array with a passivation layer over the wetting layer.
